(19) United States
(12) Patent Application Publication
(10) Pub. No.: US 2025/0202485 A1
(43) Pub. Date: Jun. 19, 2025

(54) COVERING FOR TOUCH SENSOR ELECTRODE

(71) Applicant: Cypress Semiconductor Corporation, San Jose, CA (US)

(72) Inventor: Xiaowei ZHANG, Shanghai (CN)

(73) Assignee: Cypress Semiconductor Corporation, San Jose, CA (US)

(21) Appl. No.: 18/543,220

(22) Filed: Dec. 18, 2023

(51) Int. Cl. H03K 17/96

(52) U.S. Cl. CPC H03K 17/962; H03K 2217/960705; H03K 2217/96076

(57) ABSTRACT

A touch sensor includes a sensor electrode, a touch panel overlying the sensor electrode, and a dielectric covering separating the sensor electrode from the touch panel. The dielectric covering may be configured to inhibit electrostatic discharge through the sensor electrode.

### TECHNICAL FIELD

The present disclosure relates to the field of electronics.

### BACKGROUND

Touch sensors are used in a variety of products such as household appliances, computers, industrial equipment, etc. A user may interact with a touch sensor to use and/or control a product such as a dishwasher, a laundry machine, a multi-media system, etc.

### SUMMARY

This summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

In an embodiment, a touch sensor comprises a controller, a sensor electrode connected to the controller, a touch panel overlying the sensor electrode, and a dielectric covering separating the sensor electrode from the touch panel.

In an embodiment, a touch sensor comprises a printed circuit board (PCB), a sensor electrode mounted to the PCB, a touch panel overlying the sensor electrode and the PCB, and a dielectric covering separating the sensor electrode from the touch panel.

In an embodiment, a touch sensor comprises a sensor electrode, a touch panel overlying the sensor electrode, and a dielectric covering separating the sensor electrode from the touch panel.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1A illustrates a perspective view of a dielectric cap and a sensor electrode in a disassembled state, according to some embodiments.

FIG. 1B illustrates a perspective view of a dielectric cap and a sensor electrode in an assembled state, according to some embodiments.

FIG. 1C illustrates a top view of a dielectric cap, according to some embodiments.

FIG. 1D illustrates a bottom view of a dielectric cap, according to some embodiments.

FIG. 1E illustrates a side view of a dielectric cap, according to some embodiments.

FIG. 2 illustrates a cross-sectional view of a touch sensor, according to some embodiments.

FIG. 3 illustrates a schematic view of a touch sensor, according to some embodiments.

FIG. 4 illustrates a top view of a touch sensor, according to some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

The term “over” and/or “overlying” is not to be construed as meaning only “directly over” and/or “having direct contact with”. Rather, if one element is “over” and/or “overlying” another element (e.g., a region is overlying another region), a further element (e.g., a further region) may be positioned between the two elements (e.g., a further region may be positioned between a first region and a second region if the first region is “over” and/or “overlying” the second region). Further, if a first element is “over” and/or “overlying” a second element, at least some of the first element may be vertically coincident with the second element, such that a vertical line may intersect the first element and the second element.

The term “in contact with” is not to be construed as meaning only “in direct contact with”. Rather, if one element is “in contact with” another element, the two elements may be in indirect contact with each other (e.g., a further element may be positioned between the two elements), or the two elements may be in direct contact with each other.

A touch sensor comprises a sensor electrode and a touch panel overlying the sensor electrode. In accordance with at least some embodiments of the present disclosure, a dielectric covering is disposed between the sensor electrode and the tough panel to inhibit (e.g., mitigate, suppress and/or prevent) electrostatic discharge (ESD) through the sensor electrode. The touch sensor may comprise a controller connected (e.g., electrically connected) to the sensor electrode. The controller and/or the sensor electrode may be mounted to a printed circuit board (PCB). The dielectric covering may thus protect (e.g., shield) the controller, the PCB and/or one or more (other) components (e.g., electronic components mounted to the PCB) from electrostatic discharge.

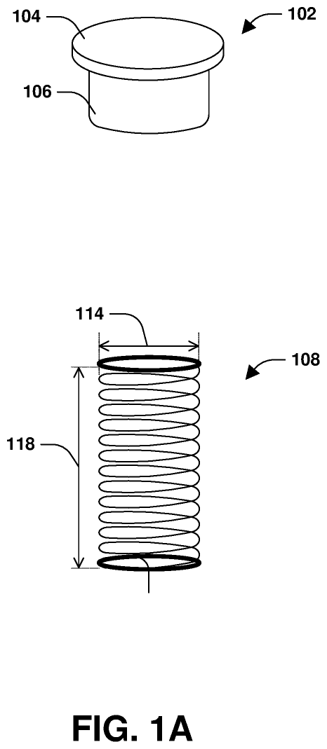

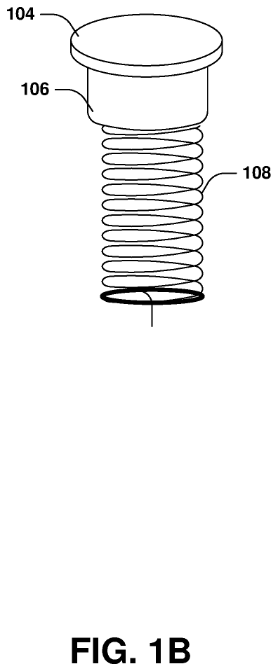

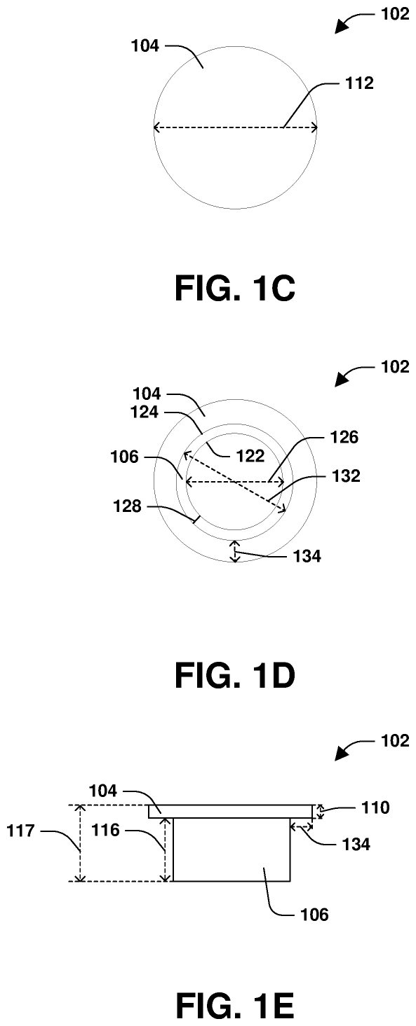

FIGS. 1A-1E illustrate a dielectric cap 102 and/or a sensor electrode 108, in accordance with some embodiments. FIG. 1A illustrates the dielectric cap 102 and the sensor electrode 108 in a disassembled state, according to some embodiments.

The dielectric cap 102 may comprise a dielectric covering 104 and a dielectric ring 106. The dielectric ring 106 may be attached to the dielectric covering 104. It will be appreciated that, as used herein, by being attached, the dielectric covering 104 and the dielectric ring 106 are not limited to comprising two separate structures that are attached. Rather, in an example, the dielectric covering 104 and the dielectric ring 106 may be integrally formed, one piece formed, a single composite piece, etc. In some examples, the dielectric covering 104 and the dielectric ring 106 may comprise two separate structures that are attached, such as with mechanical fasteners, welding, adhesives, etc. In some examples, the dielectric covering 104 and the dielectric ring 106 (e.g., the dielectric cap 102 as a whole) may be formed via at least one of 3D printing (e.g., using 3D printable material, such as 3D printable plastic), additive manufacturing, etc.

In some examples, the dielectric covering 104 comprises one or more polymers. For example, the dielectric covering 104 may comprise polyethylene (and/or one or more other polymers). Embodiments are contemplated in which the dielectric covering 104 comprises one or more non-polymer materials. In some examples, the dielectric covering 104 is transparent and/or translucent. The dielectric covering 104 may have a dielectric constant that is at least a threshold dielectric constant. In some examples, the threshold dielectric constant is 2.3. The dielectric covering 104 may have a dielectric strength that is at least a threshold dielectric strength. In some examples, the threshold dielectric strength is 50 kilovolts/millimeter.

In some examples, the dielectric ring 106 comprises the same material as the dielectric covering 104. Embodiments are contemplated in which the dielectric ring 106 comprises a different material (e.g., one or more polymers and/or one or more non-polymer materials) than the dielectric covering 104. In some examples, the dielectric ring 106 comprises one or more polymers. For example, the dielectric ring 106 may comprise polyethylene (and/or one or more other polymers). Embodiments are contemplated in which the dielectric ring 106 comprises one or more non-polymer materials. In some examples, the dielectric ring 106 is transparent and/or translucent.

In some examples, the sensor electrode 108 may be a spring electrode and/or may comprise a spring. The spring may comprise any number of coils, such as 5 coils, 10 coils, 100 coils, or other number of coils. Other structures and/or shapes of the sensor electrode 108 are contemplated. For example, the sensor electrode 108 may comprise a cylindrical object (e.g., a cylindrical rod), a cuboid-shaped object and/or other object. In some examples, the sensor electrode 108 comprises of one or more metals. Embodiments are contemplated in which the sensor electrode 108 comprises one or more non-metal materials.

In some examples, the sensor electrode 108 may have an electrode width 114 in the range of at least 2 millimeters to at most 40 millimeters, and/or in the range of at least 6 millimeters to at most 20 millimeters. Other values of the electrode width 114 are within the scope of the present disclosure. In an embodiment in which the sensor electrode 108 comprises the spring, the electrode width 114 may correspond to a spring diameter of the spring.

In some examples, the sensor electrode 108 may have an electrode height 118 in the range of at least 5 millimeters to at most 100 millimeters, and/or in the range of at least 15 millimeters to at most 40 millimeters. Other values of the electrode height 118 are within the scope of the present disclosure. In an embodiment in which the sensor electrode 108 comprises the spring, the electrode height 118 may correspond to a spring length of the spring.

FIG. 1B illustrates the dielectric cap 102 and the sensor electrode 108 in an assembled state, according to some embodiments. In some examples, the sensor electrode 108 (e.g., the spring) is fitted (e.g., plugged) into the dielectric cap 102. For example, an inner space of the dielectric cap 102 may be occupied (e.g., filled) by at least a portion of the sensor electrode 108. The inner space may be defined by an inner surface 122 (shown in FIG. 1D) of the dielectric ring 106. In some examples, the dielectric cap 102 covers at least a portion of the sensor electrode 108. A top side of the sensor electrode 108 may be covered by and/or in contact with the dielectric covering 104 of the dielectric cap 102. Alternatively and/or additionally, the inner surface 122 of the dielectric ring 106 may be in contact with the sensor electrode 108.

FIG. 1C illustrates a top view of the dielectric cap 102, according to some embodiments. In some examples, the dielectric covering 104 may have a first circular cross-section. Other shapes of the dielectric covering 104 are within the scope of the present disclosure. The dielectric covering 104 may have a diameter 112 in the range of at least 5 millimeters to at most 50 millimeters, and/or in the range of at least 10 millimeters to at most 24 millimeters. Other values of the diameter 112 are within the scope of the present disclosure.

FIG. 1D illustrates a bottom view of the dielectric cap 102, according to some embodiments. In some examples, the dielectric ring 106 may have a second circular cross-section. Other shapes of the dielectric ring 106 are within the scope of the present disclosure.

The dielectric ring 106 may have an inner diameter 126 in the range of at least 2 millimeters to at most 40 millimeters, and/or in the range of at least 6 millimeters to at most 20 millimeters. Other values of the inner diameter 126 are within the scope of the present disclosure. The inner diameter 126 may correspond to a distance between two points (e.g., opposing points) of the inner surface 122 of the dielectric ring 106. In some examples, the inner diameter 126 may be greater than the electrode width 114 (e.g., the spring diameter) of the sensor electrode 108 (e.g., the spring) (such that the sensor electrode 108 is able to be at least partially inserted into the inner space defined by the dielectric ring 106, for example). The dielectric ring 106 may have a thickness 128 in the range of at least 0.1 millimeters to at most 1 millimeter (e.g., the thickness 128 may be 0.2 millimeters). Other values of the thickness 128 are within the scope of the present disclosure. In some examples, the diameter 112 (shown in FIG. 1C) of the dielectric covering 104 is greater than an outer diameter 132 (shown in FIG. 1D) of the dielectric ring 106 such that an edge of the dielectric cap 102 is offset from an outer surface 124 of the dielectric ring 106 by a distance 134 (shown in FIG. 1D and FIG. 1E). The distance 134 may be in the range of at least 0.5 millimeters to at most 10 millimeters, and/or in the range of at least 1 millimeter to at most 2 millimeters. Other values of the distance 134 are within the scope of the present disclosure.

FIG. 1E illustrates a side view of the dielectric cap 102, according to some embodiments. In some examples, the dielectric cap 102 may have a cap height 117 in the range of at least 2 millimeters to at most 100 millimeters, and/or in the range of at least 6 millimeters to at most 10 millimeters. Other values of the cap height 117 are within the scope of the present disclosure. In some examples, the dielectric ring 106 may have a ring height 116 in the range of at least 1 millimeter to at most 100 millimeters, and/or in the range of at least 5 millimeters to at most 10 millimeters. Other values of the ring height 116 are within the scope of the present disclosure.

In some examples, the ring height 116 of the dielectric ring 106 is at least a threshold ring height. In some examples, the threshold ring height is based upon the electrode height 118 of the sensor electrode 108. In some examples, the threshold ring height is in the range of at least 0.1×hₑ to at most 0.6×hₑ, and/or in the range of at least 0.3×hₑ to at most 0.4×hₑ, where he corresponds to the electrode height 118 of the sensor electrode 108. In some examples, the threshold ring height being at least the threshold ring height results in at least a threshold proportion of the sensor electrode 108 (e.g., the spring) being surrounded and/or covered by the dielectric cap 102, which may provide for improved electrostatic discharge protection as compared to embodiments in which less than the threshold proportion of the sensor electrode 108 is covered by the dielectric cap 102.

In some examples, a thickness 110 of the dielectric covering 104 may be at least 0.1 millimeters and/or at least 0.2 millimeters. In some examples, the thickness 110 may be in a first range. The first range may range from at least 0.1 millimeters to at most 1 millimeter. Alternatively and/or additionally, the first range may range from at least 0.2 millimeters to at most 0.5 millimeters. Other values of the thickness 110 and/or the first range are within the scope of the present disclosure.

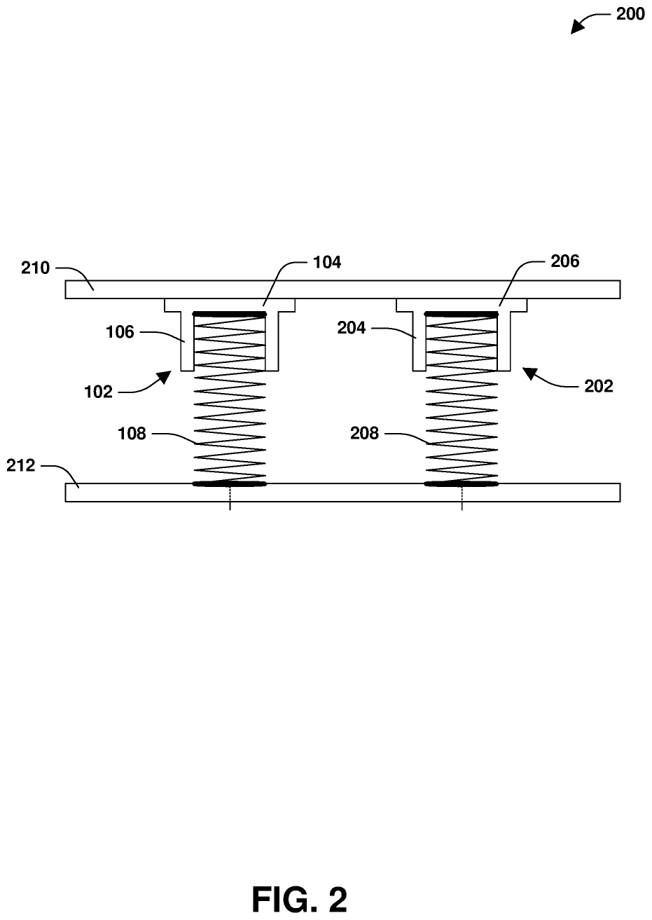

FIG. 2 illustrates a cross-sectional view of a touch sensor 200, according to some embodiments. In some examples, the touch sensor 200 comprises the sensor electrode 108, the dielectric cap 102, a second sensor electrode 208, a second dielectric cap 202, a PCB 212 and/or a touch panel 210 (e.g., a glass overlay and/or other type of touch panel). Although two electrodes are shown in FIG. 2, any number of electrodes of the touch sensor 200 are contemplated. In some examples, the sensor electrode 108 and/or the second sensor electrode 208 may be mounted to the PCB 212. In some examples, the touch panel 210 overlies the PCB 212 and/or one or more components (e.g., the sensor electrode 108, the second sensor electrode 208, diodes, transistors, chips such as integrated circuits (ICs), etc.) mounted to the PCB 212. The dielectric covering 104 may be in contact with the touch panel 210, and/or may separate the sensor electrode 108 from the touch panel 210. The second dielectric cap 202 may comprise a second dielectric covering 206 and/or a second dielectric ring 204. The second dielectric covering 206 may be in contact with the touch panel 210, and/or may separate the second sensor electrode 208 from the touch panel 210.

In some examples, the touch panel 210 serves as an interface for a device (e.g., a device comprising the touch sensor 200). The user may touch the touch panel 210 to operate a device (e.g., a device comprising the touch sensor 200). For example, when the user touches the touch panel 210, the touch may be sensed by the touch sensor 200 and/or may be interpreted as an input. The input may depend upon a location of the touch. For example, the user touching a first location of the touch panel 210 may be indicative of a first input and the user touching a second location of the touch panel 210 may be indicative of a second input. In some examples, the device may comprise a household appliance (e.g., a washing machine, a dishwasher, a refrigerator, etc.), a multi-media system, a computer, industrial equipment, or other type of device. In some examples, the user touches the touch panel 210 directly. Embodiments are contemplated in which there is a layer (e.g., a coating, lining, etc.) disposed over the touch panel 210 such that the user touches the layer (rather than directly touching the touch panel 210, for example).

In some systems that do not include the dielectric covering 104 between the sensor electrode 108 and the touch panel 210, an electrostatic discharge arc may travel from the touch panel 210 to the sensor electrode 108, the PCB 212 and/or one or more other components (e.g., components mounted to the PCB 212), which may damage (e.g., cause electrostatic damage to) the sensor electrode 108, the PCB 212 and/or the one or more other components. In some examples, the touch panel 210 may be doped with one or more metals and/or metal oxides (to achieve a certain color of the touch panel 210, for example), which may facilitate and/or accelerate flow of the electrostatic discharge arc to the sensor electrode 108, the PCB 212 and/or the one or more other components. In some examples, the dielectric covering 104 separating the sensor electrode 108 from the touch panel 210 inhibits (e.g., mitigates, suppresses and/or prevents) electrostatic discharge through the sensor electrode 108 (e.g., the dielectric covering 104 prevents the electrostatic discharge arc from traveling from the touch panel 210 to and/or through the sensor electrode 108), thereby protecting the sensor electrode 108, the PCB 212 and/or the one or more other components from electrostatic discharge. Thus, implementing the touch sensor 200 with the dielectric covering 104 between the sensor electrode 108 and the touch panel 210 may provide for improved electrostatic discharge protection for at least one of the touch sensor 200, the PCB 212, and/or the one or more other components, which may improve user safety associated with the touch sensor 200.

It may be appreciated that implementing the touch sensor 200 with the dielectric covering 104 between the sensor electrode 108 and the touch panel 210 may provide for reduced friction between the touch panel 210 and the sensor electrode 108, as compared to touch sensors which do not include the dielectric covering 104, which may protect the touch panel 210 from damage and/or may reduce wear and tear of the touch sensor 200 (e.g., the dielectric covering 104 provides a buffer between the touch panel 210 and the sensor electrode 108 such that the sensor electrode 108 does not scratch the touch panel 210).

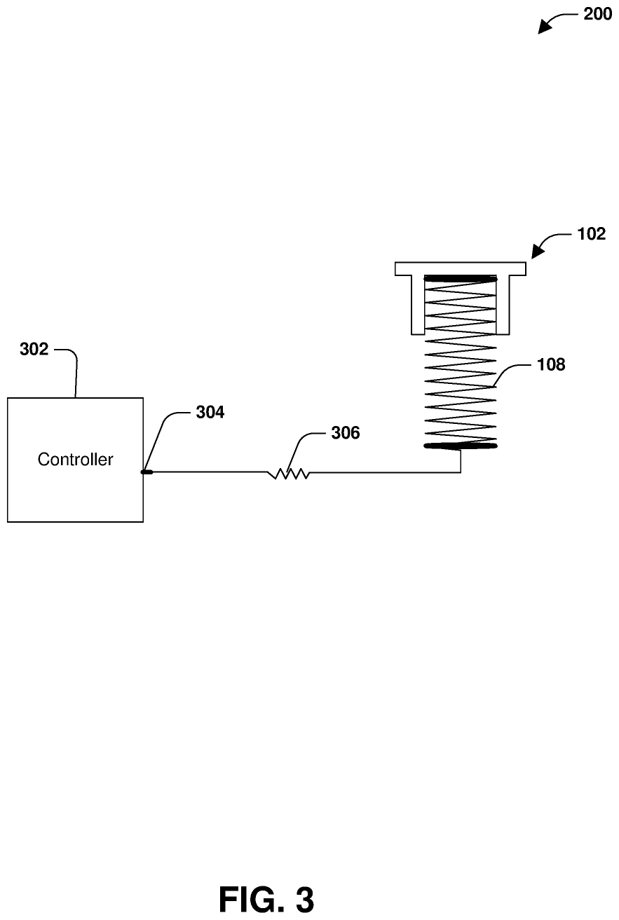

FIG. 3 illustrates a schematic view of the touch sensor 200, according to some embodiments. In some examples, the touch sensor 200 comprises a controller 302, such as a microcontroller unit (MCU) (e.g., an MCU controller). The sensor electrode 108 may be connected (e.g., electrically connected and/or capacitively connected) to the controller 302. For example, the sensor electrode 108 may be connected to a first port 304 of the controller 302. In some examples, the first port 304 comprises an input/output I/O pin. In some examples, the touch sensor 200 comprises a resistor 306 between the sensor electrode 108 and the controller 302 (e.g., the resistor 306 may be connected in series with the sensor electrode 108).

In some examples, the touch sensor 200 comprises a capacitive sensing device. In some examples, the controller 302 may determine (e.g., measure) and/or monitor a capacitance relative to the sensor electrode 108. The controller 302 may sense a touch (e.g., a user touching the touch panel 210) via detecting a change in the capacitance. In some examples, the controller 302 may determine a location of the touch (e.g., a location of the touch panel 210) based upon the capacitance relative to the sensor electrode 108 and/or other capacitances of other sensor electrodes of the touch sensor 200. The controller 302 may determine an input (e.g., a user-input) based upon the location, and/or may perform one or more actions based upon the input.

In some examples, the dielectric covering 104 separating the sensor electrode 108 from the touch panel 210 protects the controller 302 (and/or the first port 304 of the controller 302, for example) from electrostatic discharge (as a result of inhibiting electrostatic discharge through the sensor electrode 108, for example).

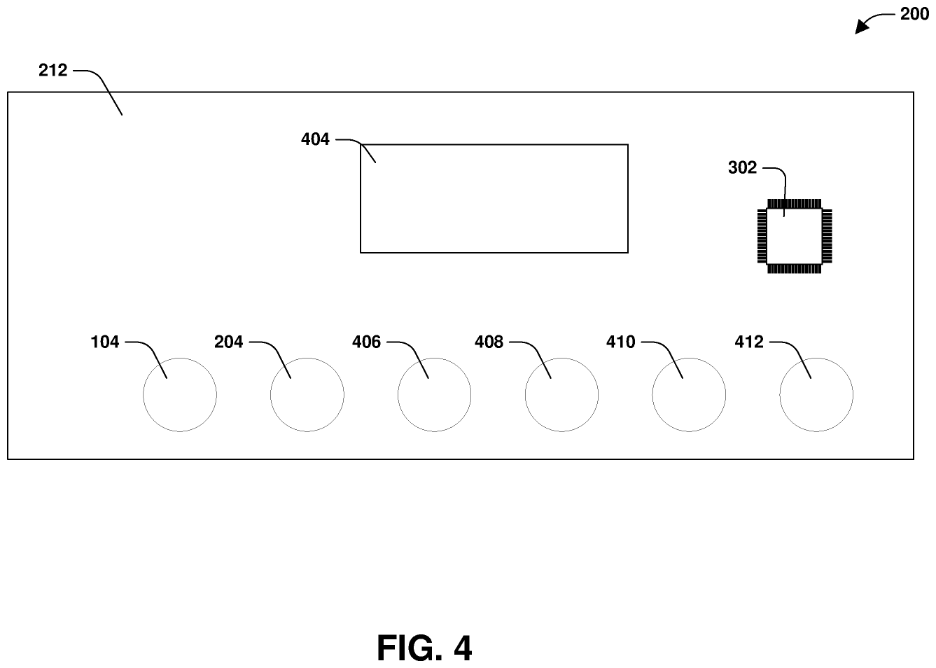

FIG. 4 illustrates a top view of the touch sensor 200, according to some embodiments. In some examples, one or more features (e.g., the touch panel 210 and/or one or more other components) of the touch sensor 200 are not included in FIG. 4 to show a top view of components (e.g., at least one of the controller 302, the PCB 212, dielectric coverings, etc.) underlying the touch panel 210. In some examples, the controller 302 may be mounted to the PCB 212. The PCB 212 may comprise traces and/or vias (not shown) to provide connections between components. For example, the controller 302 may be connected to the sensor electrode 108 via one or more traces and/or one or more vias of the PCB 212.

In some examples, the touch sensor 200 comprises a display 404 mounted to the PCB 212. The display 404 may be disposed between the PCB 212 and the touch panel 210. In some examples, at least a portion of the touch panel 210 is transparent and/or translucent to allow the display 404 to be viewed by a user through the touch panel 210. In some examples, the touch panel 210 does not overlie the display 404. In some examples, the display 404 displays one or more graphical objects indicating information comprising at least one of a time of day, a mode of operation of the device, a time elapsed since the device began a process (e.g., a dishwashing process when the device comprises a dishwasher, a clothes washing process when the device comprises a laundry machine, etc.), an indication of a touch event (e.g., an event in which a user touches the touch panel 210), etc. In some examples, the display 404 is connected to (and/or controlled by) the controller 302.

In some examples, the touch sensor 200 may comprise a third dielectric covering 406 (e.g., the third dielectric covering 406 may overlie a third sensor electrode (not shown) and/or may be part of a third dielectric cap coupled to the third sensor electrode), a fourth dielectric covering 408 (e.g., the fourth dielectric covering 408 may overlie a fourth sensor electrode (not shown) and/or may be part of a fourth dielectric cap coupled to the fourth sensor electrode), a fifth dielectric covering 410 (e.g., the fifth dielectric covering 410 may overlie a fifth sensor electrode (not shown) and/or may be part of a fifth dielectric cap coupled to the fifth sensor electrode), and/or a sixth dielectric covering 412 (e.g., the sixth dielectric covering 412 may overlie a sixth sensor electrode (not shown) and/or may be part of a sixth dielectric cap coupled to the sixth sensor electrode). Although six dielectric coverings are shown in FIG. 4, any number of dielectric coverings of the touch sensor 200 are contemplated.

The touch sensor 200 and/or the controller 302 may have one or more functionalities in addition to touch sensing functionality, such as, but not limited to, at least one of processing one or more touch events detected by the touch sensor 200 to determine an input, storing a record of the input in a memory storage component, performing one or more actions based upon the input, etc. In an example in which the device comprises a refrigerator, the input may be indicative of modifying a cooling setting. Accordingly, the one or more actions may include setting the cooling setting of the refrigerator to a new value (e.g., a value, such as a cooling temperature, indicated by the input).

In some examples, the touch sensor 200 and/or the device may be required to comply with one or more regulations (e.g., one or more electrostatic discharge regulations) established by one or more regulatory agencies, such as IEC61000 Apr. 2 Level 4 (e.g., contact discharge protection of 8 kilovolts and/or air discharge protection of 15 kilovolts) and/or one or more other regulations. It may be appreciated that by using the techniques of the present disclosure, the touch sensor 200 and/or the device may satisfy the one or more regulations, such as due, at least in part, to the dielectric covering 104 separating the sensor electrode 108 from the touch panel 210 to inhibit electrostatic discharge through the sensor electrode 108 (e.g., the dielectric covering 104 prevents an electrostatic discharge arc from traveling from the touch panel 210 to and/or through the sensor electrode 108). Some systems rely upon (high-cost) electronic protection devices, such as electrostatic discharge protection diodes, to suppress electrostatic discharges and/or satisfy the one or more regulations. It may be appreciated that, in accordance with some embodiments of the present disclosure, the dielectric covering 104 may inhibit electrostatic discharges and/or satisfy the one or more regulations, and thus the touch sensor 200 and/or the device may be implemented without the electronic protection devices, thereby reducing production cost of the touch sensor 200 and/or the device and/or providing for a smaller PCB size (as a result of not requiring room on the PCB 212 for the electronic protection devices, for example).

In some examples, the thickness 110 of the dielectric covering 104 being in the first range may provide for improved electrostatic discharge protection and/or improved operation of the touch sensor 200. For example, the thickness 110 being in the first range may inhibit electrostatic discharges and/or satisfy the one or more regulations with little to no negative impact on touch sensing capability of the touch sensor 200 (e.g., the controller 302 is able to accurately measure capacitance relative to the sensor electrode 108 and/or accurately sense touch events when the thickness 110 is in the first range) to allow for desired functioning of the touch sensor 200 and/or the device.

In some examples, a breakdown voltage of the dielectric covering 104 may be at least a threshold breakdown voltage. The threshold breakdown voltage may be 10 kilovolts or 20 kilovolts. Other values of the threshold breakdown voltage are within the scope of the present disclosure. In some examples, the breakdown voltage of the dielectric covering 104 being at least the threshold breakdown voltage may provide for improved electrostatic discharge protection and/or improved operation of the touch sensor 200 while allowing for desired functioning of the touch sensor 200. For example, the breakdown voltage of the dielectric covering 104 being at least the threshold breakdown voltage may inhibit electrostatic discharges and/or satisfy the one or more regulations.

In some embodiments of the present disclosure, the dielectric covering 104 is not part of the dielectric cap 102. In some examples, the dielectric covering 104 may comprise at least one of a layer, a coating, tape (e.g., plastic tape), etc. between the sensor electrode 108 and the touch panel 210.

In an embodiment, a touch sensor comprises a controller, a sensor electrode connected to the controller, a touch panel overlying the sensor electrode, and a dielectric covering separating the sensor electrode from the touch panel.

In an embodiment, the dielectric covering is configured to protect the controller from electrostatic discharge.

In an embodiment, the sensor electrode comprises a spring.

In an embodiment, the touch sensor comprises a dielectric cap comprising the dielectric covering and a dielectric ring surrounding at least a portion of the spring.

In an embodiment, the dielectric covering has a first circular cross-section, and/or the dielectric ring has a second circular cross-section.

In an embodiment, the controller detects a change in capacitance relative to the sensor electrode to sense a touch.

In an embodiment, the touch sensor comprises a printed circuit board (PCB) to which the sensor electrode and the controller are mounted.

In an embodiment, the PCB comprises a trace and/or a via, wherein the sensor electrode is connected to the controller via the trace and/or the via.

In an embodiment, the touch sensor comprises a display mounted to the PCB and connected to the controller.

In an embodiment, the controller comprises a microcontroller unit (MCU).

In an embodiment, the dielectric covering comprises polyethylene.

In an embodiment, a thickness of the dielectric covering is at least 0.1 millimeters.

In an embodiment, a breakdown voltage of the dielectric covering is at least 10 kilovolts.

In an embodiment, a touch sensor comprises a printed circuit board (PCB), a sensor electrode mounted to the PCB, a touch panel overlying the sensor electrode and the PCB, and a dielectric covering separating the sensor electrode from the touch panel.

In an embodiment, the dielectric covering is configured to protect the PCB from electrostatic discharge.

In an embodiment, the sensor electrode comprises a spring.

In an embodiment, the touch sensor comprises a dielectric cap comprising the dielectric covering and a dielectric ring surrounding at least a portion of the spring.

In an embodiment, the dielectric covering has a first circular cross-section and/or the dielectric ring has a second circular cross-section.

In an embodiment, a touch sensor comprises a sensor electrode, a touch panel overlying the sensor electrode, and a dielectric covering separating the sensor electrode from the touch panel.

In an embodiment, the dielectric covering is configured to inhibit electrostatic discharge through the sensor electrode.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used in this application, the terms “component,” “module,” “system”, “interface”, and/or the like are generally intended to refer to a computer-related entity, either hardware, a combination of hardware and software, software, or software in execution. One or more components may be localized on one computer and/or distributed between two or more computers.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” is intended to encompass a computer program accessible from any computer-readable device, carrier, or media. Of course, those skilled in the art will recognize many modifications may be made to this configuration without departing from the scope or spirit of the claimed subject matter.

Various operations of embodiments are provided herein. In one embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering may be implemented without departing from the scope of the disclosure. Further, it will be understood that not all operations are necessarily present in each embodiment provided herein. Also, it will be understood that not all operations are necessary in some embodiments.

Any aspect or design described herein as an “example” and/or the like is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. A touch sensor comprising:
a controller;
a sensor electrode connected to the controller;
a touch panel overlying the sensor electrode; and
a dielectric covering separating the sensor electrode from the touch panel.

2. The touch sensor of claim 1, wherein:
the dielectric covering is configured to protect the controller from electrostatic discharge.

3. The touch sensor of claim 1, wherein:
the sensor electrode comprises a spring.

4. The touch sensor of claim 3, comprising:
a dielectric cap comprising:
the dielectric covering; and
a dielectric ring surrounding at least a portion of the spring.

5. The touch sensor of claim 4, wherein at least one of:
the dielectric covering has a first circular cross-section; or the dielectric ring has a second circular cross-section.

6. The touch sensor of claim 1, wherein:
the controller detects a change in capacitance relative to the sensor electrode to sense a touch.

7. The touch sensor of claim 1, comprising:
a printed circuit board (PCB) to which the sensor electrode and the controller are mounted.

8. The touch sensor of claim 7, wherein:
the PCB comprises at least one of:
a trace; or
a via; and
the sensor electrode is connected to the controller via at least one of the trace or the via.

9. The touch sensor of claim 8, comprising:
a display mounted to the PCB and connected to the controller.

10. The touch sensor of claim 1, wherein:
the controller comprises a microcontroller unit (MCU).

11. The touch sensor of claim 1, wherein:
the dielectric covering comprises polyethylene.

12. The touch sensor of claim 1, wherein:
a thickness of the dielectric covering is at least 0.1 millimeters.

13. The touch sensor of claim 1, wherein:
a breakdown voltage of the dielectric covering is at least 10 kilovolts.

14. A touch sensor comprising:
a printed circuit board (PCB);
a sensor electrode mounted to the PCB;
a touch panel overlying the sensor electrode and the PCB; and
a dielectric covering separating the sensor electrode from the touch panel.

15. The touch sensor of claim 14, wherein:
the dielectric covering is configured to protect the PCB from electrostatic discharge.

16. The touch sensor of claim 14, wherein:
the sensor electrode comprises a spring.

17. The touch sensor of claim 16, comprising:
a dielectric cap comprising:
the dielectric covering; and
a dielectric ring surrounding at least a portion of the spring.

18. The touch sensor of claim 17, wherein at least one of:
the dielectric covering has a first circular cross-section; or the dielectric ring has a second circular cross-section.

19. A touch sensor comprising:
a sensor electrode;
a touch panel overlying the sensor electrode; and
a dielectric covering separating the sensor electrode from the touch panel.

20. The touch sensor of claim 19, wherein:
the dielectric covering is configured to inhibit electrostatic discharge through the sensor electrode.
